(19) United States
(12) Patent Application Publication
(10) Pub. No.: US 2026/0353642 A1
(43) Pub. Date: Nov. 5, 2026

(54) SEMICONDUCTOR DEVICE WITH T-SHAPED BURIED GATE ELECTRODE AND METHOD FOR MANUFACTURING THE SAME

(71) Applicant: NANYA TECHNOLOGY CORPORATION, NEW TAIPEI CITY (TW)

(72) Inventors: MENG-ZHEN LI, NEW TAIPEI CITY (TW); JUI-HSIU JAO, NEW TAIPEI CITY (TW)

(21) Appl. No.: 19/214,479

(22) Filed: May 21, 2025

Related U.S. Application Data
(63) Continuation of application No. 19/194,389, filed on Apr. 30, 2025.

(51) Int. Cl. H10B 12/00

(52) U.S. Cl. CPC H10B 12/34; H10B 12/053

(57) ABSTRACT

The present disclosure provides a semiconductor device with a T-shaped buried gate electrode and a method for preparing the semiconductor device. The semiconductor device includes a semiconductor substrate having a plurality of long active areas; a first gate electrode disposed in a dielectric layer over the semiconductor substrate and extending into the substrate; and a first source/drain region and a second source/drain region disposed in the long active region and located at opposite sides of the first gate electrode. The long active areas extend along a first direction and are parallel to each other. The first gate electrode has a first portion extending across the long active region and a second portion extending into the first source/drain region.

### CROSS-REFERENCE TO RELATED APPLICATION

This application is a continuation application of U.S. Non-Provisional application Ser. No. 19/194,389 filed Apr. 30, 2025, which is incorporated herein by reference in its entirety.

### TECHNICAL FIELD

The present disclosure relates to a semiconductor device and a method for manufacturing a semiconductor device, and more particularly, to a semiconductor device with a T-shape buried gate electrode and a method for preparing a semiconductor device with a T-shaped buried gate electrode.

### DISCUSSION OF THE BACKGROUND

Semiconductor devices are essential for many modern applications. With advancements of electronic technology, semiconductor devices are becoming smaller in size while providing greater functionality and incorporating larger amounts of integrated circuitry. A dynamic random-access memory (DRAM) device, which consists of numerous memory cells, is one of the most popular volatile semiconductor memory devices in use today. Each memory cell comprises a transistor and a capacitor, with the transistor and capacitor connected in series. The memory cells are organized into memory arrays and are addressed via a word line and a bit line; one addresses a column of memory cells while the other addresses a row. By using the word line and the bit line, a DRAM cell can be read and programmed.

Moreover, as semiconductor fabrication technology continues to improve, sizes of semiconductor devices are reduced, and the sizes of memory cells decrease correspondingly. Accordingly, gate control ability for these memory cells becomes a serious issue in memory devices.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device. The semiconductor device includes a semiconductor substrate having a plurality of long active areas; a first gate electrode disposed in a dielectric layer over the semiconductor substrate and extending into the substrate; and a first source/drain region and a second source/drain region disposed in the long active region and located at opposite sides of the first gate electrode. The long active areas extend along a first direction and are parallel to each other. The first gate electrode has a first portion extending across the long active region and a second portion extending into the first source/drain region.

Another aspect of the present disclosure provides a semiconductor device. The semiconductor device includes a semiconductor substrate; a plurality of long active areas disposed in the substrate; a first gate structure disposed in a dielectric layer over the semiconductor substrate and extending into the semiconductor substrate; and a first source/drain region and a second source/drain region disposed in the long active region and located at opposite sides of the first gate structure. The long active areas extend along a first direction and are parallel to each other. The first gate structure comprises a first word line insulating layer, a first word line barrier layer, a first word line conductive layer, and a first word line capping layer. The first word line conductive layer has a first portion extending across the long active region and a second portion extending into the first source/drain region.

Another aspect of the present disclosure provides a method for fabricating a semiconductor device. The method includes forming an isolation structure in a semiconductor substrate to define a long active region; forming a doped region in the long active region; forming a dielectric layer over the substrate; etching the dielectric layer and the semiconductor substrate to form a first trench and a second trench; and forming a first gate electrode in the first trench and a second gate electrode in the second trench. The first trench has a first portion extending across the doped region and a second portion extending away from the first portion, and the second trench has a third portion extending across the doped region and a fourth portion extending away from the third portion. The first portion of the first trench and the third portion of the second trench penetrate through the doped region to form a first source/drain region, a second source/drain region, and a third source/drain region, and the second source/drain region is located between the first trench and the second trench. The second portion of the first trench extends into the first source/drain region, and the fourth portion of the second trench extends into the third source/drain region. The second portion of the first trench exposes three sides of the first source/drain region, and the fourth portion of the second trench exposes three sides of the third source/drain region.

Another aspect of the present disclosure provides a method for fabricating a semiconductor device. The method includes providing a substrate; forming a word line trench in a dielectric layer over the substrate and into the substrate; conformally forming an insulating layer in the word line trench and conformally forming a barrier layer on the insulating layer; conformally forming a nucleation layer on the first barrier layer; performing a post-treatment to the nucleation layer, wherein the post-treatment comprises a reducing agent comprising diborane and a tungsten-containing precursor; forming a bulk layer on the nucleation layer; and performing a planarization process to turn the insulating layer, the barrier layer, and the conductive layer into a first word line insulating layer, a first word line barrier layer, a first word line conductive layer, a second word line insulating layer, a second word line barrier layer, and a second word line conductive layer, respectively. The nucleation layer and the bulk layer configure a conductive layer. The nucleation layer and the bulk layer comprise tungsten.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed herein may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a top view illustrating a semiconductor device in accordance with some embodiments of the present disclosure.

FIG. 2 is a cross-sectional view illustrating a semiconductor device along a sectional line I-I′ in FIG. 1 in accordance with some embodiments of the present disclosure.

FIG. 3 is a schematic top view illustrating a portion of a semiconductor device in accordance with some embodiments of the present disclosure.

FIG. 4A is a top view illustrating a semiconductor device in accordance with various embodiments of the present disclosure.

FIG. 4B is a top view illustrating a semiconductor device in accordance with various embodiments of the present disclosure.

FIG. 5 is a cross-sectional view illustrating a semiconductor device along a sectional line C-C′ in FIG. 4A or FIG. 4B in accordance with various embodiments of the present disclosure.

FIG. 6 is a flow diagram illustrating a method of forming a semiconductor device in accordance with some embodiments of the present disclosure.

FIG. 7 is a top view illustrating an intermediate stage of forming an isolation structure to define active regions during the formation of the semiconductor device in accordance with some embodiments of the present disclosure.

FIG. 8 is a cross-sectional view illustrating an intermediate stage of forming an isolation structure to define active regions during the formation of the semiconductor device along the sectional line I-I′ in FIG. 7 in accordance with some embodiments of the present disclosure.

FIG. 9 is a top view illustrating an intermediate stage of forming trenches in a semiconductor substrate during the formation of the semiconductor device in accordance with some embodiments of the present disclosure.

FIG. 10 is a cross-sectional view illustrating an intermediate stage of forming trenches in a semiconductor substrate during the formation of the semiconductor device along the sectional line I-I′ in FIG. 9 in accordance with some embodiments of the present disclosure.

FIG. 11 is a top view illustrating an intermediate stage of forming gate dielectric layers lining the trenches during the formation of the semiconductor device in accordance with some embodiments of the present disclosure.

FIG. 12 is a cross-sectional view illustrating an intermediate stage of forming gate dielectric layers lining the trenches during the formation of the semiconductor device along the sectional line I-I′ in FIG. 11 in accordance with some embodiments of the present disclosure.

FIG. 13 is a top view illustrating an intermediate stage of filling the trenches with a gate electrode material during the formation of the semiconductor device of the present disclosure in accordance with some embodiments of the present disclosure.

FIG. 14 is a cross-sectional view illustrating an intermediate stage of filling the trenches with a gate electrode material during the formation of the semiconductor device along the sectional line I-I′ in FIG. 13 in accordance with some embodiments of the present disclosure.

FIG. 15 is a top view illustrating an intermediate stage of recessing the gate electrode material to form gate structures during the formation of the semiconductor device in accordance with some embodiments of the present disclosure.

FIG. 16 is a cross-sectional view illustrating an intermediate stage of recessing the gate electrode material to form gate structures during the formation of the semiconductor device along the sectional line I-I′ in FIG. 15 in accordance with some embodiments of the present disclosure.

FIG. 17 is a top view illustrating an intermediate stage of forming a dielectric cap layer covering the gate structures during the formation of the semiconductor device in accordance with some embodiments of the present disclosure.

FIG. 18 is a cross-sectional view illustrating an intermediate stage of forming a dielectric cap layer covering the gate structures during the formation of the semiconductor device along the sectional line I-I′ in FIG. 17 in accordance with some embodiments of the present disclosure.

FIG. 19 is a top view illustrating an intermediate stage of removing a portion of the dielectric cap layer during the formation of the semiconductor device in accordance with some embodiments of the present disclosure.

FIG. 20 is a cross-sectional view illustrating an intermediate stage of removing a portion of the dielectric cap layer during the formation of the semiconductor device along the sectional line I-I′ in FIG. 19 in accordance with some embodiments of the present disclosure.

FIG. 21A is a top view illustrating a typical arrangement of active areas for shrinking active areas in the manufacturing for a semiconductor device.

FIG. 21B is a top view illustrating an arrangement of long active areas and dummy areas in the manufacturing for a semiconductor device in accordance with various embodiments of the present disclosure.

FIG. 22 is a top view illustrating an intermediate stage of forming trenches during the formation of a semiconductor device in accordance with some embodiments of the present disclosure.

FIG. 23 is a cross-sectional view illustrating an intermediate stage of forming trenches during the formation of a semiconductor device along a sectional line C-C′ in FIG. 21B in accordance with some embodiments of the present disclosure.

FIG. 24 is a cross-sectional view illustrating an intermediate stage of forming an insulating layer, a barrier layer, and a nucleation layer during the formation of a semiconductor device along a sectional line C-C′ in FIG. 21B in accordance with some embodiments of the present disclosure.

FIG. 25 is a graph representing reducing agent pulses and interval times of a post-treatment in accordance with some embodiments of the present disclosure.

FIG. 26 is a cross-sectional view illustrating an intermediate stage of forming a bulk layer during the formation of a semiconductor device along a sectional line C-C′ in FIG. 21B in accordance with some embodiments of the present disclosure.

FIG. 27 is a cross-sectional view illustrating an intermediate stage of forming word line insulating layers, word line barrier layers, and word line conductive layers during the formation of a semiconductor device along a sectional line C-C′ in FIG. 21B in accordance with some embodiments of the present disclosure.

FIG. 28 is a cross-sectional view illustrating an intermediate stage of forming gate structures during the formation of a semiconductor device along a sectional line C-C′ in FIG. 21B in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

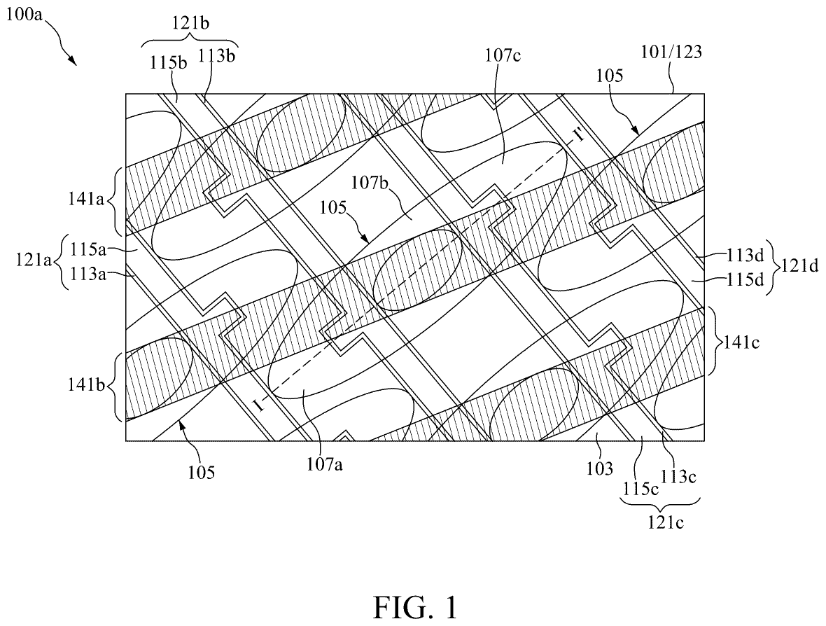

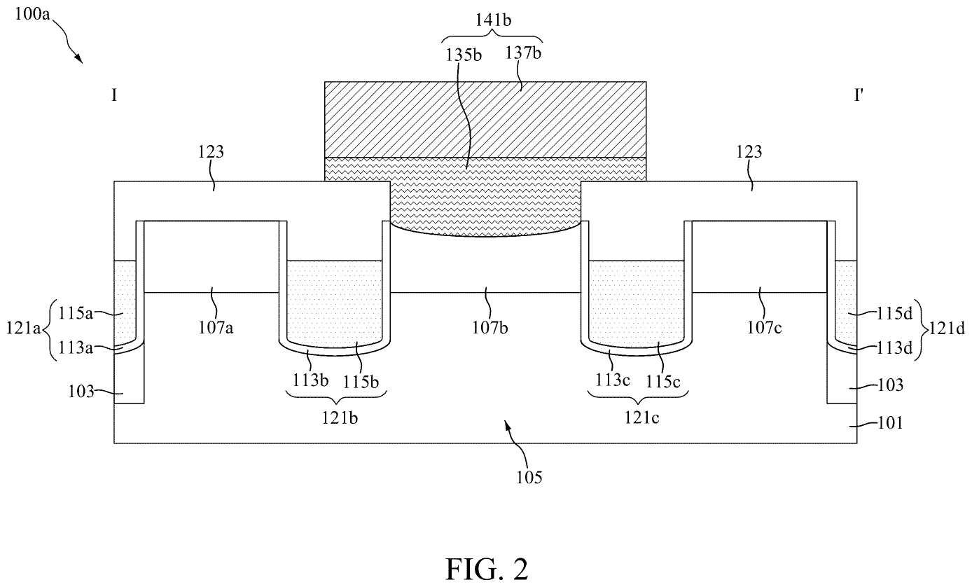

FIG. 1 is a top view illustrating a semiconductor device 100a, and FIG. 2 is a cross-sectional view illustrating the semiconductor device 100a along a sectional line I-I′ in FIG. 1 in accordance with some embodiments of the present disclosure. As shown in FIGS. 1 and 2, the semiconductor device 100a includes a plurality of active regions 105, a plurality of gate structures 121a, 121b, 121c, and 121d, and a plurality of bit line structures 141a, 141b, and 141c.

In some embodiments, the active regions 105 are defined by an isolation structure 103 disposed in a semiconductor substrate 101, and the gate structures 121a, 121b, 121c, and 121d are buried in the semiconductor substrate 101. In the present embodiment, the semiconductor device 100a is a dynamic random-access memory (DRAM) device, and the buried gate structures 121a, 121b, 121c, and 121d serve as buried word lines for the DRAM. Although only four word lines are illustrated, it is understood that more than four word lines may be implemented in the semiconductor device 100a.

Moreover, in some embodiments, each of the active regions 105 is intersected by two adjacent gate structures and each of the active regions 105 has three source/drain regions separated by the two adjacent gate structures. For example, as shown in FIGS. 1 and 2, source/drain regions 107a, 107b, and 107c are disposed in one of the active regions 105. The source/drain regions 107a and 107b are located at two opposite sides of the gate structure 121b, and the source/drain regions 107b and 107c are located at two opposite sides of the gate structure 121c, in accordance with some embodiments of the present disclosure. In addition, the source/drain region 107b is located between the gate structures 121b and 121c, and the source/drain region 107b serves as a common source/drain region which is electrically connected to the bit line structure 141b.

Each of the gate structures 121a, 121b, 121c, and 121d includes a gate dielectric layer and a gate electrode. For example, the gate structure 121a is composed of a gate dielectric layer 113a and a gate electrode 115a surrounded by the gate dielectric layer 113a, and the gate structure 121b is composed of a gate dielectric layer 113b and a gate electrode 115b surrounded by the gate dielectric layer 113b. Similarly, the gate structure 121c is composed of a gate dielectric layer 113c and a gate electrode 115c surrounded by the gate dielectric layer 113c, and the gate structure 121d is composed of a gate dielectric layer 113d and a gate electrode 115d surrounded by the gate dielectric layer 113d. In some embodiments, the gate electrodes 115a, 115b, 115c, and 115d are separated from the semiconductor substrate 101 by the gate dielectric layers 113a, 113b, 113c, and 113d, respectively.

It should be noted that the gate structures 121a, 121b, 121c, and 121d have “T” shape structures in the top view of FIG. 1 in accordance with some embodiments. Specifically, in some embodiments, the gate electrodes 115a, 115b, 115c, and 115d of the gate structures 121a, 121b, 121c, and 121d have “T” shape structures in the top view of FIG. 1. The details are described below. In addition, the gate structures 121a, 121b, 121c, and 121d are covered by a dielectric cap layer 123, which is configured to protect and isolate the gate electrodes 115a, 115b, 115c, and 115d from the conductive features disposed above.

Still referring to FIGS. 1 and 2, the semiconductor device 100a also includes the bit line structures 141a, 141b, and 141c. As shown in FIG. 2, the bit line structure 141b is electrically connected to the source/drain region 107b between the gate structures 121b and 121c, in accordance with some embodiments. Although only three bit line structures are illustrated in the top view of FIG. 1, it is understood that more than three bit line structures may be implemented in the semiconductor device 100a. In the present embodiment, the semiconductor device 100a is a DRAM device, and the source/drain regions 107a and 107c are electrically connected to respective capacitors (not shown).

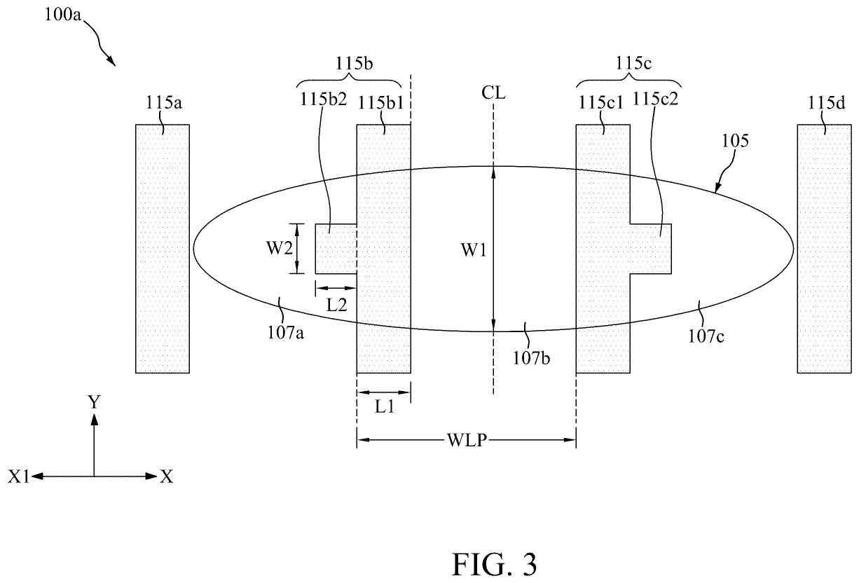

FIG. 3 is a schematic top view illustrating a portion of the semiconductor device 100a, in accordance with some embodiments. It should be noted that some of the features, such as the gate dielectric layers 113a, 113b, 113c, and 113d, and the bit line structures 141a, 141b, and 141c, are omitted from FIG. 3 in order to clarify the sizes, the profiles and the locations of the gate electrodes 115a, 115b, 115c, and 115d.

As shown in FIG. 3, the source/drain region 107a is between the gate electrodes 115a and 115b, the source/drain region 107b is between the gate electrodes 115b and 115c, and the source/drain region 107c is between the gate electrodes 115c and 115d. In some embodiments, the gate electrode 115b includes a portion 115b1 extending across the active region 105 and a portion 115b2 protruding (extending away) from the portion 115b1, and the gate electrode 115c includes a portion 115c1 extending across the active region 105 and a portion 115c2 protruding (extending away) from the portion 115c1. Although the gate electrodes 115a and 115d do not include any protruding portions in the top view of FIG. 3, the gate electrodes 115a and 115d may include protruding portions within other active regions 105, as shown in the top view of FIG. 1.

In some embodiments, the portion 115b2 of the gate electrode 115b is closer to the gate electrode 115a than the portion 115b1 of the gate electrode 115b, and the portion 115c2 of the gate electrode 115c is closer to the gate electrode 115d than the portion 115c1 of the gate electrode 115c. In some embodiments, the portion 115b2 of the gate electrode 115b extends into the source/drain region 107a, and the portion 115c2 of the gate electrode 115c extends into the source/drain region 107c.

As shown in FIG. 3, the X1-direction is opposite to the X-direction, and the Y-direction is perpendicular to the X-direction and the X1-direction. In some embodiments, the portion 115b2 of the gate electrode 115b and the portion 115c2 of the gate electrode 115c extend parallel to each other but in opposite directions. In particular, the gate electrode 115a, the portion 115b1 of the gate electrode 115b, the portion 115c1 of the gate electrode 115c, and the gate electrode 115d extend along the Y-direction, the portion 115b2 of the gate electrode 115b extends along the X1 direction, and the portion 115c2 of the gate electrode 115c extends along the X-direction, in accordance with some embodiments. That is, the portions 115b1 and 115b2 of the gate electrode 115b form a right angle, and the portions 115c1 and 115c2 of the gate electrode 115c form a right angle.

In some embodiments, the portion 115b2 of the gate electrode 115b and the portion 115c2 of the gate electrode 115c are within the same active region 105. In some embodiments, the portion 115b2 of the gate electrode 115b and the portion 115c2 of the gate electrode 115c do not extend to the isolation structure 103 outside of the active region 105. Furthermore, the portion 115b2 of the gate electrode 115b and the portion 115c2 of the gate electrode 115c are separated from the gate electrodes 115a and 115d.

In particular, the source/drain region 107a surrounds three sides of the portion 115b2 of the gate electrode 115b, and the source/drain region 107c surrounds three sides of the portion 115c2 of the gate electrode 115c, in accordance with some embodiments. In some embodiments, the portions 115b1 and 115b2 of the gate electrode 115b form a T-shaped structure, and the portions 115c1 and 115c2 of the gate electrode 115c form another T-shaped structure in the schematic top view of FIG. 3. It should be noted that the two T-shaped structures are mirror images across the central line CL of the active region 105.

Still referring to FIG. 3, the active region 105 has a maximum width W1 along the Y-direction, and the portion 115b2 has a width W2 along the Y-direction. In some embodiments, the ratio (W2/W1) of the width W2 to the maximum width W1 is greater than 0 and smaller than about 0.5. The portion 115b1 has a length L1 along the X-direction (or the X1-direction), and the portion 115b2 has a length L2 along the X-direction (or the X1-direction). The length L2 is less than a word line pitch WLP of the semiconductor device 100a. In some embodiments, the ratio (L2/L1) of the length L2 to the length L1 is in a range from about 0.5 to about 1. The portion 115c2 of the gate electrode 115c has similar features as the above-mentioned features of the portion 115b2 of the gate electrode 115b, and details thereof are not repeated herein.

Since the gate electrodes 115b and 115c of the semiconductor device 100a have the portions 115b2 and 115c2 protruding from the portions 115b1 and 115c1, respectively, the effective gate width (i.e., effective channel width) may be increased, and the saturation current may be increased. Thus, the gate control ability may be improved, and the operation speed of the semiconductor device 100a may be increased. In particular, the charging and discharging rates of the transistors (e.g., the transistor composed of the gate electrode 115b and the source/drain regions 107a and 107b, and the transistor composed of the gate electrode 115c and the source/drain regions 107b and 107c) may be increased, and the write speeds of the capacitors coupled to the transistors may be improved, which significantly improves the overall device performance.

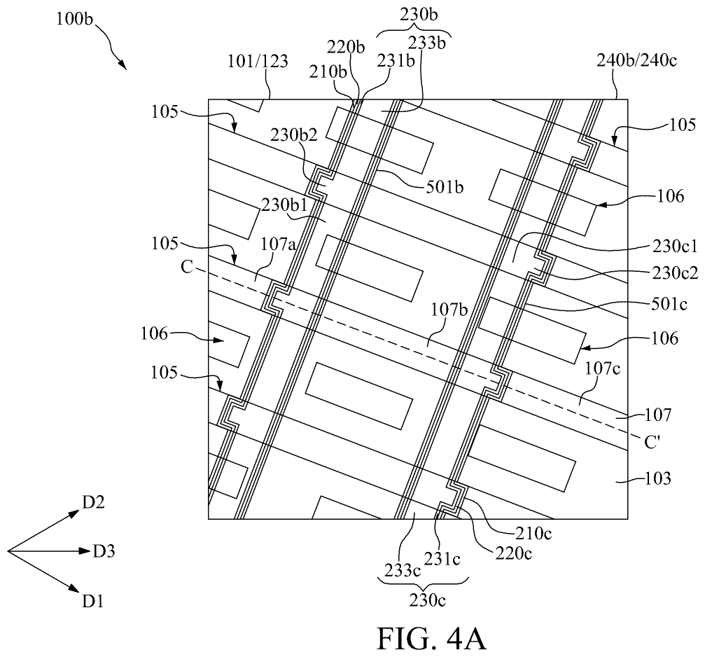

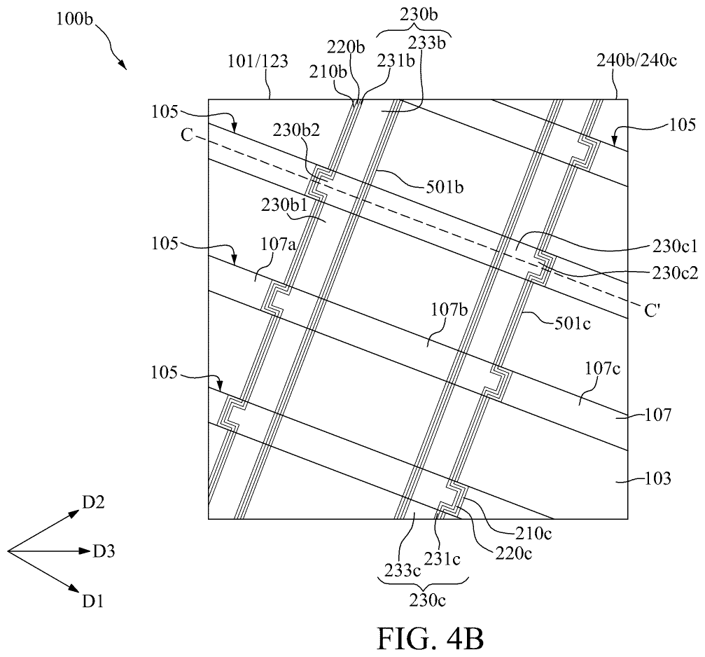

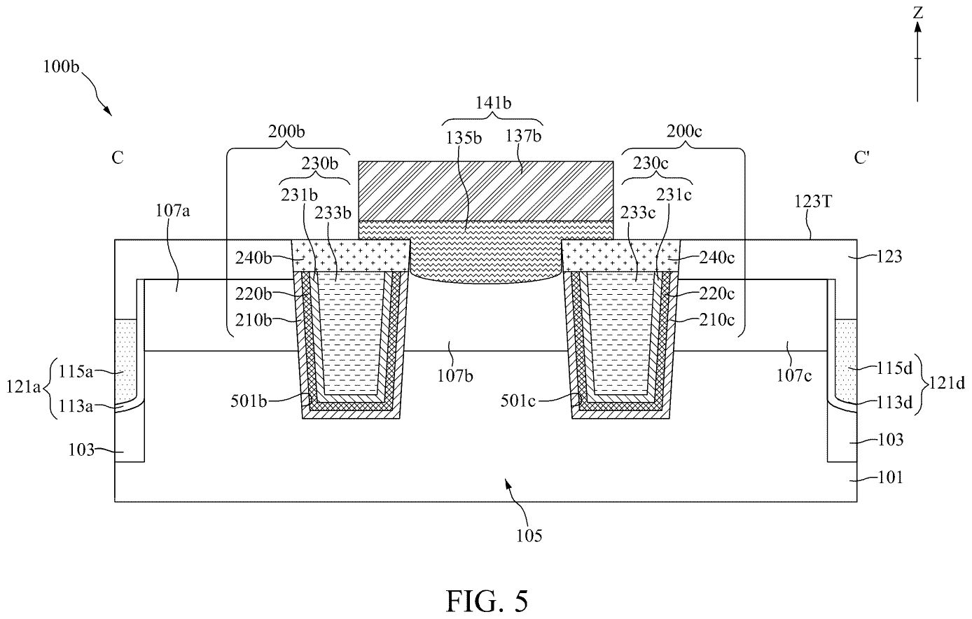

FIGS. 4A and 4B are schematic top views illustrating a portion of a semiconductor device 100b in accordance with various embodiments of the present disclosure. FIG. 5 is a cross-sectional view illustrating the semiconductor device 100b along a sectional line C-C′ in FIG. 4A or FIG. 4B in accordance with various embodiments of the present disclosure. The semiconductor device 100b is similar to the semiconductor device 100a in FIG. 1. Elements in FIGS. 4A and 4B that are same as or similar to elements in FIG. 1 are marked with similar reference numbers and duplicative descriptions are omitted.

With reference to FIGS. 4A, 4B, and 5, the semiconductor device 100b may include a plurality of gate structures 200b and 200c. As shown in FIG. 4A, the gate structures 200b and 200c may be implemented with both a plurality of long active areas 105 and a plurality of dummy active areas 106. In contrast, FIG. 4B shows that the gate structures 200b and 200c may be implemented only with the long active areas 105, omitting the dummy active areas 106.

With reference to FIG. 4A, the long active areas 105 may be arranged in a parallel configuration, extending consistently along a specific direction designated as D1. In some embodiments, the long active areas 105 may be part of a test element group (TEG), a structure used in semiconductor manufacturing and testing to evaluate and validate various parameters and performance during the manufacturing process. In addition, the arrangement of the long active areas 105 facilitated a uniform distribution, which can enhance overall performance and efficiency of a semiconductor device.

The dummy active areas 106 may be positioned between two adjacent long active areas 105. In some embodiments, the dummy active areas 106 located between two adjacent long active areas 105 may be arranged serially in the direction D1 and separated from each other. In some embodiments, the dummy active areas 106 positioned in different pairs of the long active areas 105 may be arranged alternately. In some embodiments, the dummy active areas 106 positioned in different pairs of the long active areas 105 may be arranged in a direction D2, which is a mirror direction of the direction D1 with respect to a reference direction D3.

Typically, the dummy active areas 106 serve as regions in the semiconductor device 100b that do not perform any significant functional role. Instead, the dummy active areas 106 provide structural support, ensure spacing between components, and help monitor and control process consistency during semiconductor manufacturing.

With reference to FIG. 5, the gate structure 200b may be formed within a trench 501b disposed in the dielectric cap layer 123 and extending into the substrate 101. The gate structure 200b may include a word line insulating layer 210b, a word line barrier layer 220b, a word line conductive layer 230b, and a word line capping layer 240b. In some embodiments, the word line conductive layer 230b may serve as a gate electrode. In some embodiments, from a top view perspective, as shown in FIG. 4A, the word line conductive layer 230b may have a first portion 230b1 extending across the doped region 107 in the long active areas 105 and a second portion 230b2 extending away from the first portion 230b1.

The word line insulating layer 210b may be disposed in and lining the trench 501b. In some embodiments, the word line insulating layer 210b may include a high-k material, an oxide, a nitride, an oxynitride or a combination thereof.

The word line barrier layer 220b may be conformally disposed on the word line insulating layer 210b. In some embodiments, the word line barrier layer 220b may be formed of, for example, titanium nitride. In some embodiments, the word line barrier layer 220b may include a columnar grain structure.

The word line conductive layer 230b may include a nucleation portion 231b and a bulk portion 233b. The nucleation portion 231b may be conformally disposed on the word line barrier layer 220b. The bulk portion 233b of the word line conductive layer 230b may be disposed in the trench 501b and surrounded by the nucleation portion 231b. The word line conductive layer 230b may serve as a gate electrode. In some embodiments, from a top view perspective, as shown in FIG. 4A, the word line conductive layer 230b may have a first portion 230b1 extending across the doped region 107 in the long active areas 105 and a second portion 230b2 extending away from the first portion 230b1. In some embodiments, the nucleation portion 231b and the bulk portion 233b of the word line conductive layer 230b may include tungsten.

The word line capping layer 240b may be disposed within the trench 501b, over the word line insulating layer 210b, the word line barrier layer 220b, and the word line conductive layer 230b, and may cap the word line insulating layer 210b, the word line barrier layer 220b and the word line conductive layer 230b. In some embodiments, the word line barrier layer 220b is formed of, for example, silicon oxide, silicon nitride, silicon oxynitride, or silicon nitride oxide.

Similarly, the gate structure 200c may be formed within a trench 501c disposed in the dielectric cap layer 123 and extending into the substrate 101. The gate structure 200c may include a word line insulating layer 210c, a word line barrier layer 220c, a word line conductive layer 230c, and a word line capping layer 240c.

The word line insulating layer 210c may be disposed in and lining the trench 501c. In some embodiments, the word line insulating layer 210c may include a high-k material, an oxide, a nitride, an oxynitride or a combination thereof.

The word line barrier layer 220c may be conformally disposed on the word line insulating layer 210c. In some embodiments, the word line barrier layer 220c may be formed of, for example, titanium nitride. In some embodiments, the word line barrier layer 220c may include a columnar grain structure.

The word line conductive layer 230c may include a nucleation portion 231c and a bulk portion 233c. The nucleation portion 231c may be conformally disposed on the word line barrier layer 220c. The bulk portion 233c of the word line conductive layer 230c may be disposed in the trench 501c and surrounded by the nucleation portion 231c. The word line conductive layer 230c may serve as a gate electrode. In some embodiments, from a top view perspective, as shown in FIG. 4A, the word line conductive layer 230c may have a first portion 230c1 extending across the doped region 107 in the long active areas 105 and a second portion 230c2 extending away from the first portion 230c1. In some embodiments, the nucleation portion 231c and the bulk portion 233c of the word line conductive layer 230c may include tungsten.

The word line capping layer 240c may be disposed within the trench 501c, over the word line insulating layer 210c, the word line barrier layer 220c, and the word line conductive layer 230c, and may cap the word line insulating layer 210c, the word line barrier layer 220c and the word line conductive layer 230c. In some embodiments, the word line barrier layer 220c is formed of, for example, silicon oxide, silicon nitride, silicon oxynitride, or silicon nitride oxide.

With reference to FIG. 4B, another embodiment of the semiconductor device 100b is presented. The arrangement of the long active areas 105 in FIG. 4B may be same as the arrangement of the long active areas 105 in FIG. 4A, and the preparation of the semiconductor device 100b in FIG. 4B is also identical to that of the semiconductor device 100b in FIG. 4A; therefore, repeated descriptions are omitted. In other words, the preparation of dummy active area 106 is skipped or omitted in FIG. 4B.

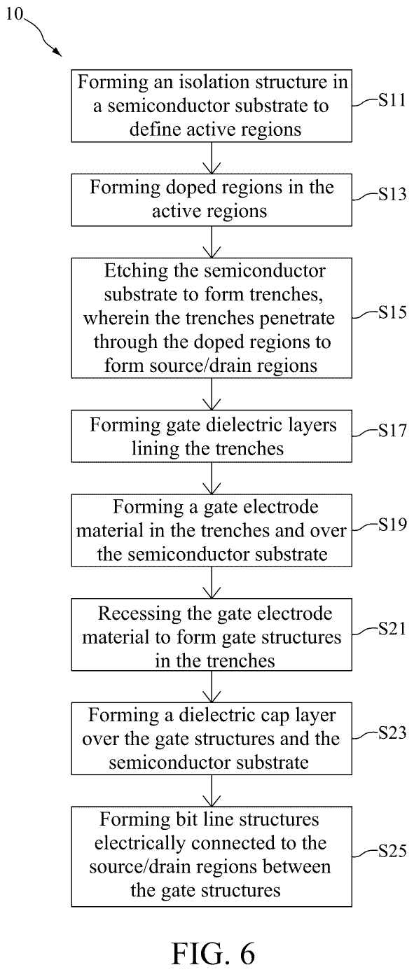

FIG. 6 is a flow diagram illustrating a method 10 for forming the semiconductor device 100a or 100b, and the method 10 includes steps S11, S13, S15, S17, S19, S21, S23, and S25, in accordance with some embodiments. The steps S11 to S25 of FIG. 6 are elaborated upon in connection with the following figures.

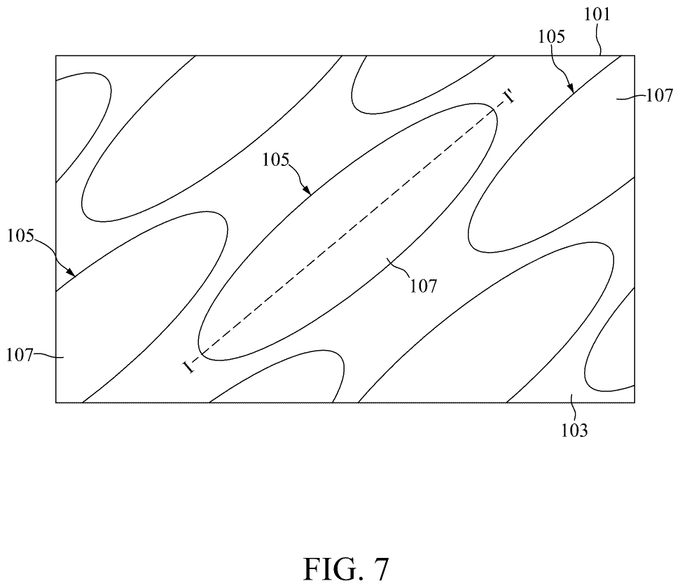

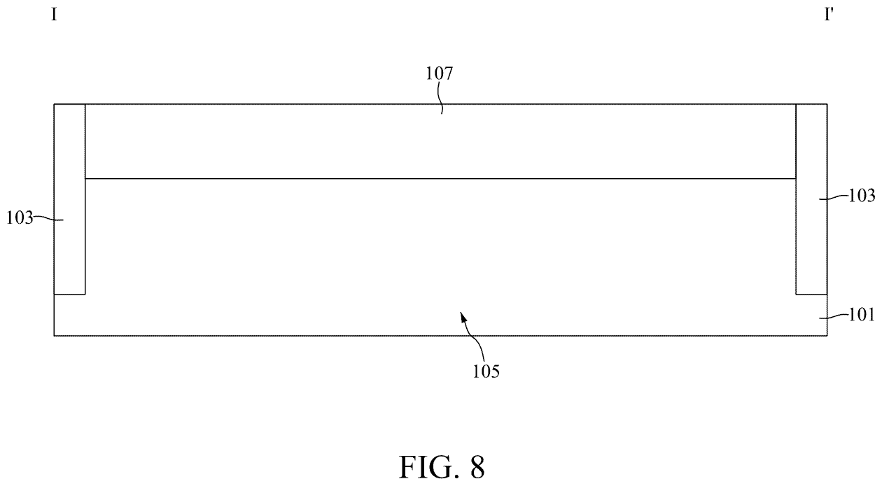

FIGS. 7, 9, 11, 13, 15, 17, and 19 are top views illustrating intermediate stages in the formation of the semiconductor device 100a. FIGS. 8, 10, 12, 14, 16, 18, and 20 are cross-sectional views along a sectional line I-I′ in FIGS. 7, 9, 11, 13, 15, 17, and 19, respectively, illustrating intermediate stages in the formation of the semiconductor device 100a, in accordance with some embodiments.

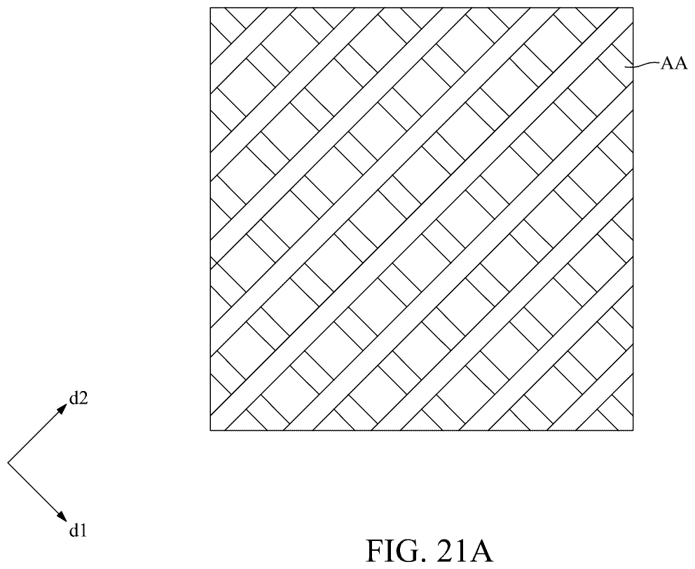

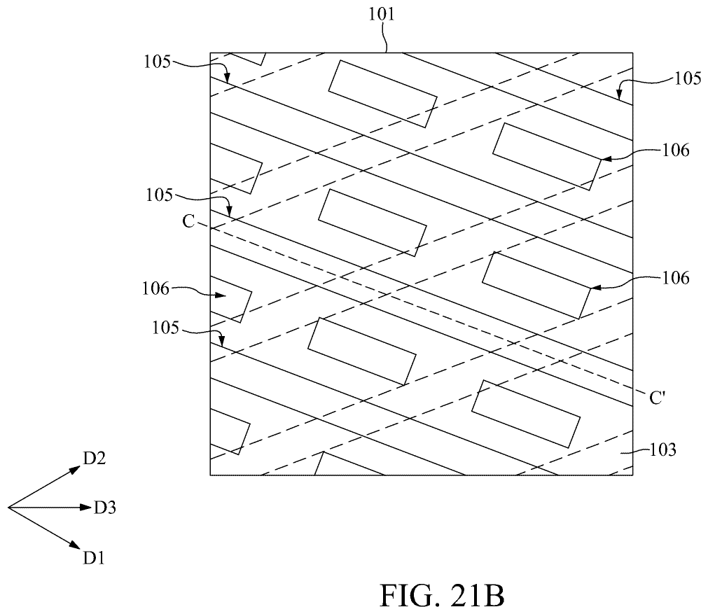

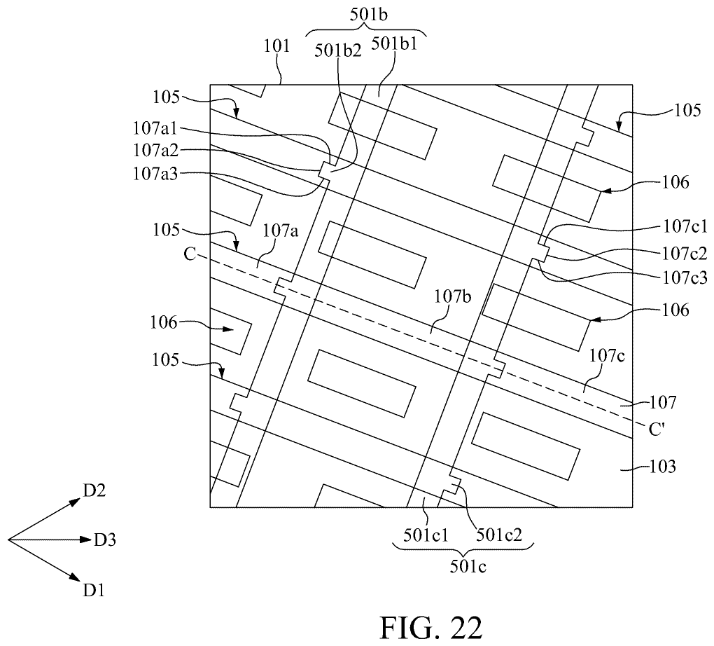

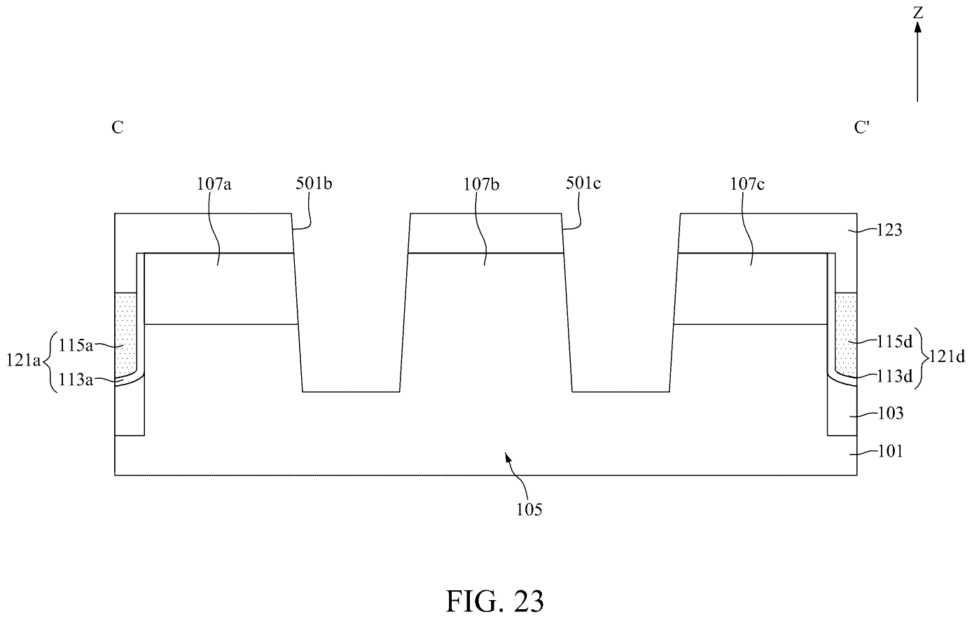

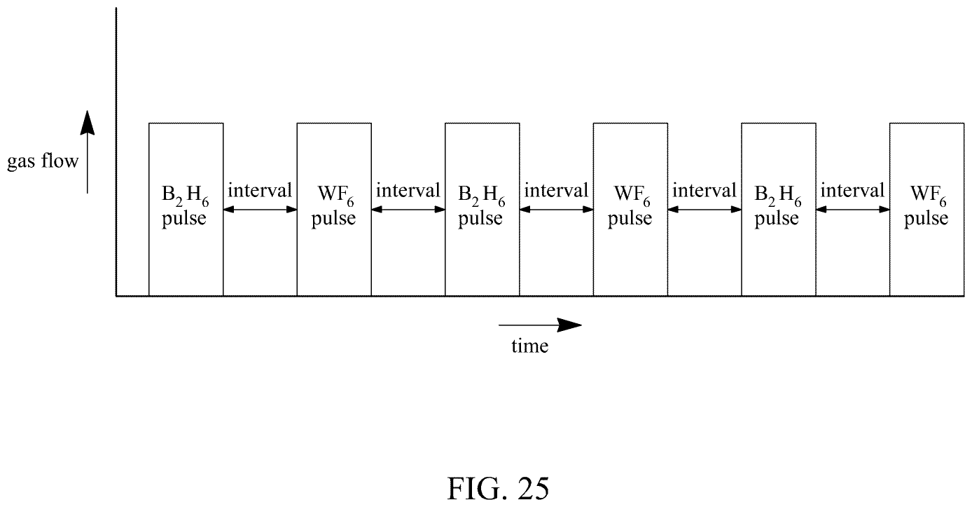

FIGS. 21A, 21B, and 22 are top views illustrating intermediate stages in the formation of the semiconductor device 100b. FIGS. 23, 24, 26, 27, and 28 are cross-sectional views along a sectional line C-C′ in FIG. 21B illustrating intermediate stages in the formation of the semiconductor device 100b, in accordance with some embodiments. FIG. 25 is a graph representing reducing agent pulses and interval times of a post-treatment in accordance with some embodiments of the present disclosure.

As shown in FIGS. 7 and 8, the semiconductor substrate 101 is provided. The semiconductor substrate 101 may be a semiconductor wafer such as a silicon wafer. In some embodiments, the semiconductor substrate 101 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP.

In some embodiments, the semiconductor substrate 101 includes an epitaxial layer. For example, the semiconductor substrate 101 has an epitaxial layer overlying a bulk semiconductor. In some embodiments, the semiconductor substrate 101 is a semiconductor-on-insulator substrate which may include a substrate, a buried oxide layer over the substrate, and a semiconductor layer over the buried oxide layer, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other applicable methods.

Still referring to FIGS. 7 and 8, the isolation structure 103 is formed in the semiconductor substrate 101 to define the active regions 105, and the isolation structure 103 is a shallow trench isolation (STI) structure, in accordance with some embodiments. The respective step is illustrated as the step S11 in the method 10 shown in FIG. 6. In addition, the isolation structure 103 may be made of silicon oxide, silicon nitride, silicon oxynitride or another applicable dielectric material, and the formation of the isolation structure 103 may include forming a patterned mask (not shown) over the semiconductor substrate 101, etching the semiconductor substrate 101 to form openings (not shown) by using the patterned mask as a mask, depositing a dielectric material in the openings and over the semiconductor substrate 101, and polishing the dielectric material until the semiconductor substrate 101 is exposed.

Moreover, doped regions 107 are formed in the active regions 105 defined by the isolation structure 103. The respective step is illustrated as the step S13 in the method 10 shown in FIG. 6. In some embodiments, the doped regions 107 are formed by one or more ion implantation processes, and P-type dopants, such as boron (B), gallium (Ga), or indium (In), or N-type dopants, such as phosphorous (P) or arsenic (As), can be implanted in the active regions 105 to form the doped regions 107, depending on the conductivity type of the semiconductor device 100a. In addition, the doped regions 107 will become the source/drain regions of the semiconductor device 100a in the subsequent processes.

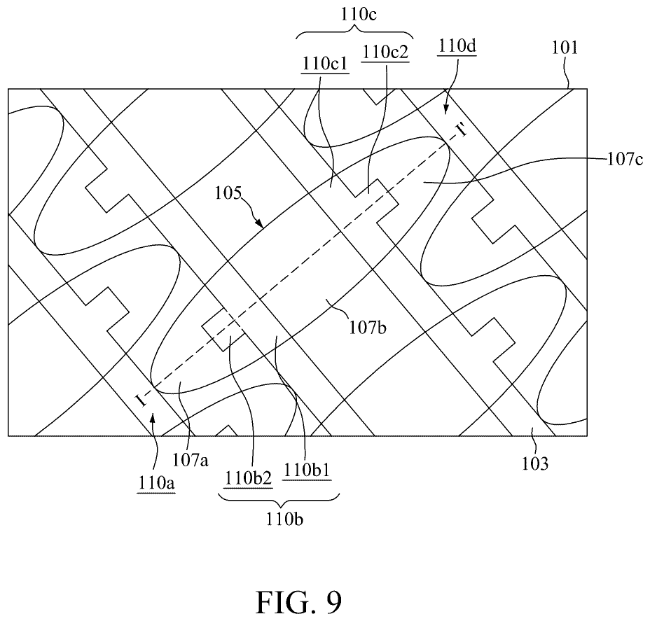

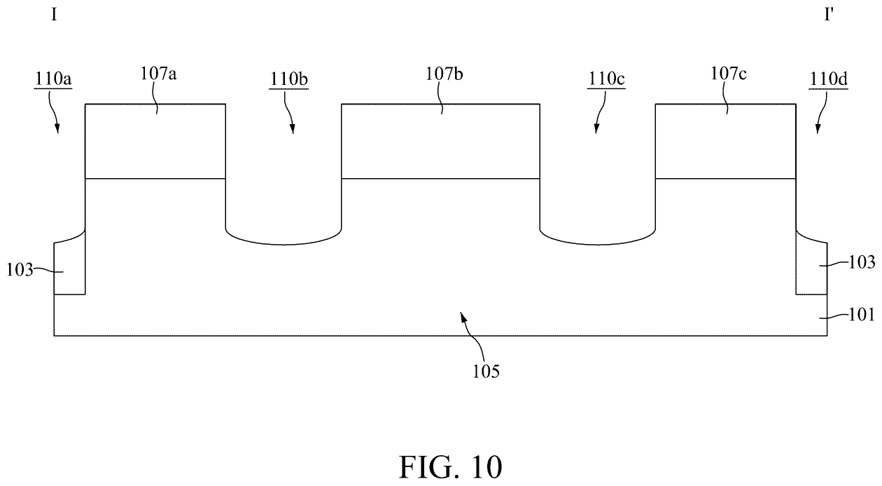

After the doped regions 107 are formed, the semiconductor substrate 101 is etched to form trenches 110a, 110b, 110c, and 110d, as shown in FIGS. 9 and 10 in accordance with some embodiments. The respective step is illustrated as the step S15 in the method 10 shown in FIG. 6. As shown in FIG. 10, the trenches 110a and 110d expose the isolation structure 103, and the trenches 110b and 110c penetrate through the doped regions 107 to form source/drain regions 107a, 107b, and 107c. In some embodiments, the source/drain region 107a is between the trenches 110a and 110b, the source/drain region 107b is between the trenches 110b and 110c, and the source/drain region 107c is between the trenches 110c and 110d.

It should be noted that the trench 110b includes a portion 110b1 extending across the active region 105 and a portion 110b2 protruding (extending away) from the portion 110b1, and the trench 110c includes a portion 110c1 extending across the active region 105 and a portion 110c2 protruding (extending away) from the portion 110c1. In some embodiments, the portion 110b2 of the trench 110b extends into the source/drain region 107a, and the portion 110c2 of the trench 110c extends into the source/drain region 107c.

Moreover, the portion 110b2 of the trench 110b and the portion 110c2 of the trench 110c extend parallel to each other but in opposite directions. In some embodiments, the portions 110b2 and 110c2 are within the same active region 105. In particular, the portion 110b2 of the trench 110b exposes three sides of the source/drain region 107a, and the portion 110c2 of the trench 110c exposes three sides of the source/drain region 107c, in accordance with some embodiments.

The formation of the trenches 110a, 110b, 110c, and 100d may include forming a patterned mask (not shown) over the semiconductor substrate 101, and etching the semiconductor substrate 101 by using the patterned mask as a mask. In some embodiments, to achieve a high fidelity pattern transfer from the patterned mask to the semiconductor substrate 101, an extreme ultraviolet (EUV) lithography process is utilized to form the trenches 110a, 110b, 110c, and 100d. After the trenches 110a, 110b, 110c, and 100d are formed, the pattered mask may be removed.

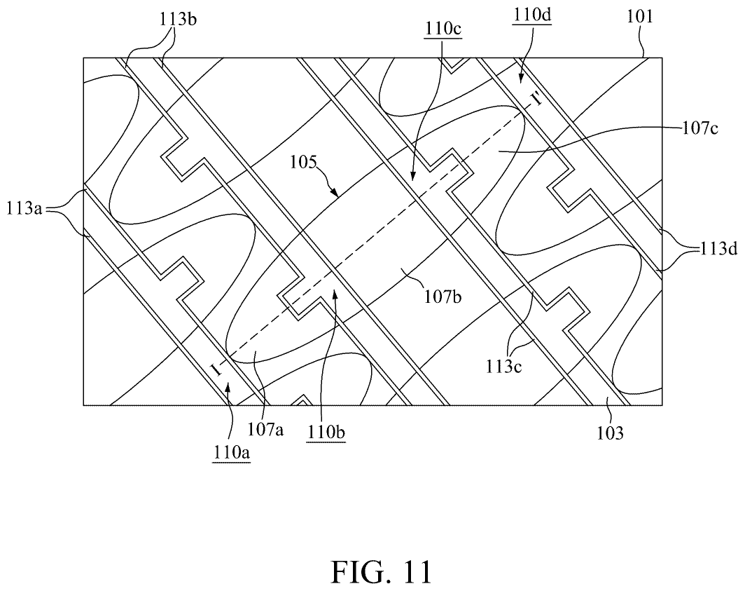

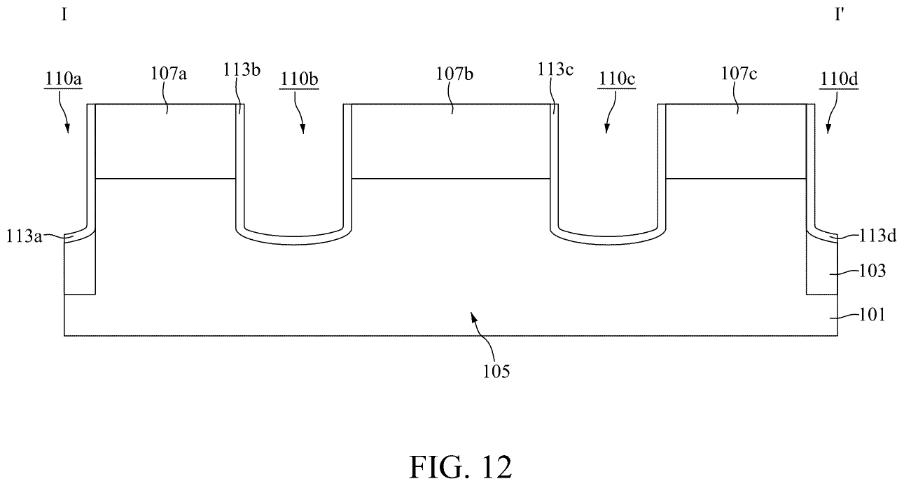

Next, the gate dielectric layers 113a, 113b, 113c, and 113d are formed lining the inner surfaces of the trenches 110a, 110b, 110c, and 110d, as shown in FIGS. 11 and 12 in accordance with some embodiments. The respective step is illustrated as the step S17 in the method 10 shown in FIG. 6. In some embodiments, the gate dielectric layers 113a, 113b, 113c, and 113d are made of silicon oxide, silicon nitride, silicon oxynitride, a dielectric material with high dielectric constant (high-k), or a combination thereof.

In addition, the formation of the gate dielectric layers 113a, 113b, 113c, and 113d may include conformally depositing a gate dielectric material (not shown) over the inner surfaces of the trenches 110a, 110b, 110c, and 110d and the top surface of the semiconductor substrate 101 (i.e., the top surfaces of the source/drain regions 107a, 107b, and 107c), and a planarization process is performed on the gate dielectric material to expose the semiconductor substrate 101. The deposition process of the gate dielectric material may include a chemical vapor deposition (CVD) process, a physical vapor deposition (PVD) process, an atomic layer deposition (ALD) process, a spin-coating process, or another applicable process. The planarization process of the gate dielectric material may be a chemical mechanical polishing (CMP) process.

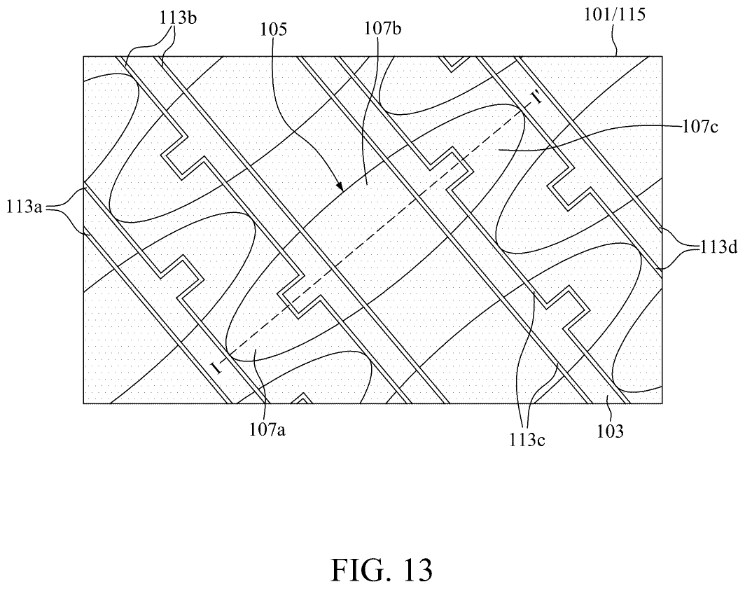

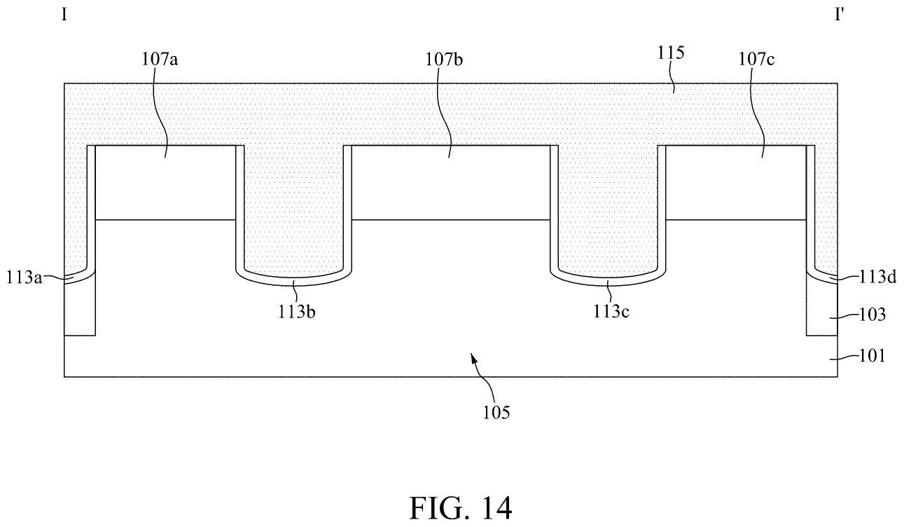

After the gate dielectric layers 113a, 113b, 113c, and 113d are formed, a gate electrode material 115 is formed in the trenches 110a, 110b, 110c and 110d and over the top surface of the semiconductor substrate 101, as shown in FIGS. 13 and 14 in accordance with some embodiments. The respective step is illustrated as the step S19 in the method 10 shown in FIG. 6. In some embodiments, a barrier layer (not shown) is formed between the gate dielectric layers 113a, 113b, 113c, and 113d and the gate electrode material 115.

Moreover, in some embodiments, the gate electrode material 115 is made of a conductive material such as aluminum (Al), copper (Cu), tungsten (W), titanium (Ti), tantalum (Ta), or another applicable material. In some embodiments, the gate electrode material 115 is formed by one or more deposition processes. The deposition process may include a CVD process, a PVD process, an ALD process, a plasma enhanced chemical vapor deposition (PECVD) process, a metal organic chemical vapor deposition (MOCVD) process, a plating process, a sputtering process or another applicable deposition process.

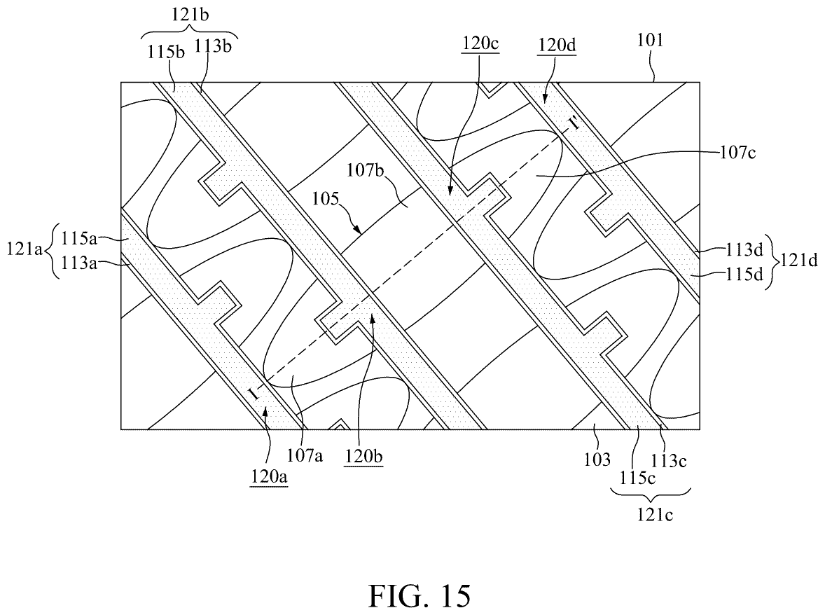

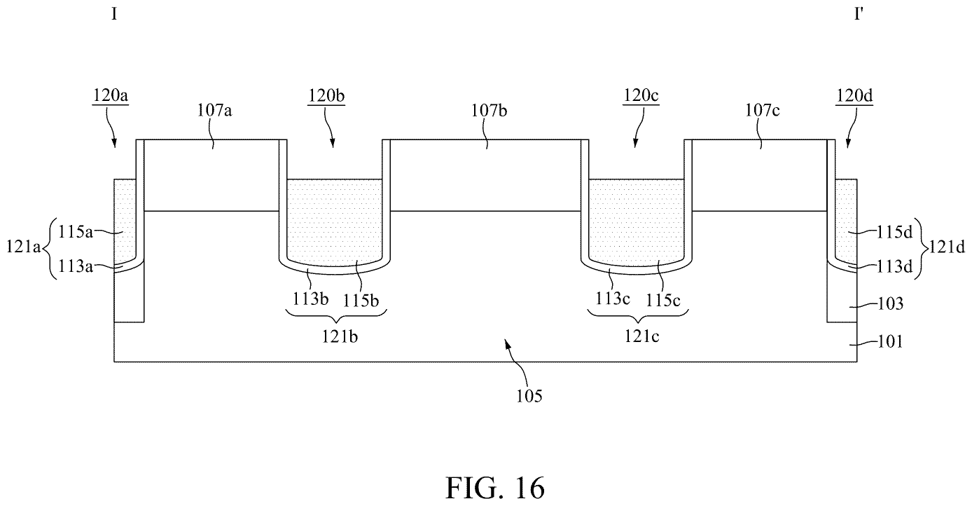

Subsequently, the gate electrode material 115 is recessed to form the gate structures 121a, 121b, 121c, and 121d in the trenches 110a, 110b, 110c, and 110d (see FIGS. 11 and 12), as shown in FIGS. 15 and 16 in accordance with some embodiments. The respective step is illustrated as the step S21 in the method 10 shown in FIG. 6. In some embodiments, the gate electrode material 115 is recessed through an etch-back process, such that gate electrodes 115a, 115b, 115c, and 115d are formed in the trenches 110a, 110b, 110c, and 110d. In some embodiments, the etch-back process includes a wet etching process, a dry etching process, or a combination thereof.

In some embodiments, the gate structure 121a includes the gate dielectric layer 113a and the gate electrode 115a, the gate structure 121b includes the gate dielectric layer 113b and the gate electrode 115b, the gate structure 121c includes the gate dielectric layer 113c and the gate electrode 115c, and the gate structure 121d includes the gate dielectric layer 113d and the gate electrode 115d. Moreover, recesses 120a, 120b, 120c, and 120d are obtained over the gate electrodes 115a, 115b, 115c, and 115d. In some embodiments, the gate dielectric layers 113a, 113b, 113c, and 113d are located at opposite sides of the recesses 120a, 120b, 120c, and 120d.

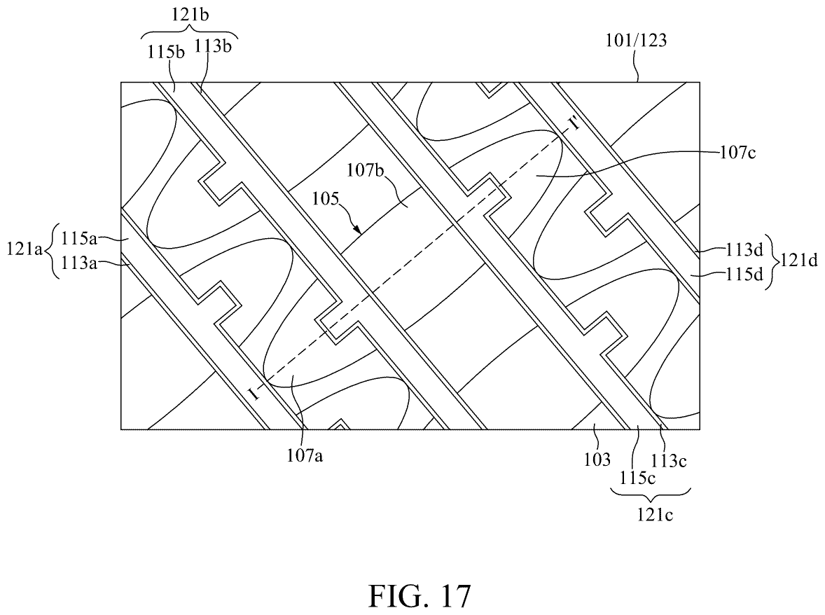

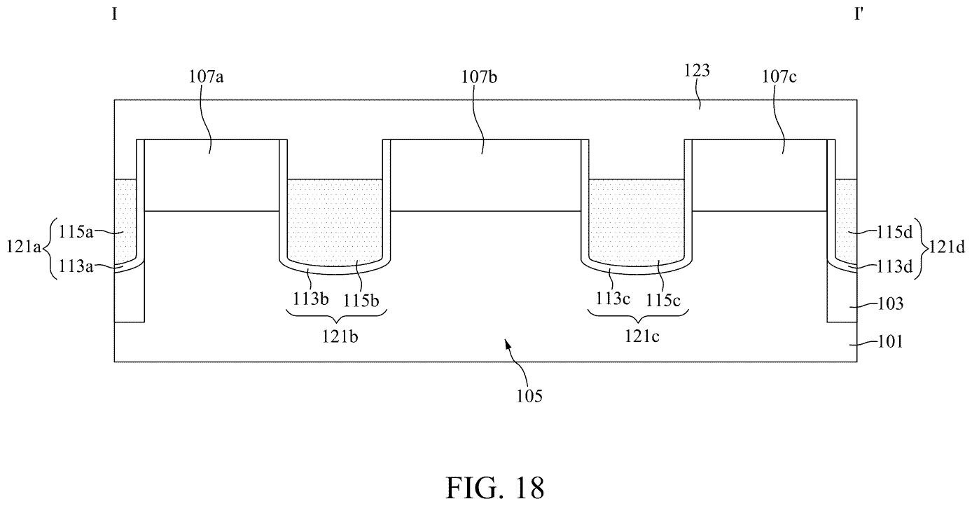

Next, a dielectric cap layer 123 is formed over the gate structures 121a, 121b, 121c, and 121d and covering the top surface of the semiconductor substrate 101, as shown in FIGS. 17 and 18 in accordance with some embodiments. The respective step is illustrated as the step S23 in the method 10 shown in FIG. 6. In some embodiments, the recesses 120a, 120b, 120c, and 120d (see FIGS. 15 and 16) are filled by the dielectric cap layer 123. In some embodiments, the dielectric cap layer 123 is made of silicon oxide, silicon nitride, silicon oxynitride, or another applicable dielectric material, and the dielectric cap layer 123 is formed by a CVD process, a PVD process, a spin coating process, another applicable process, or a combination thereof.

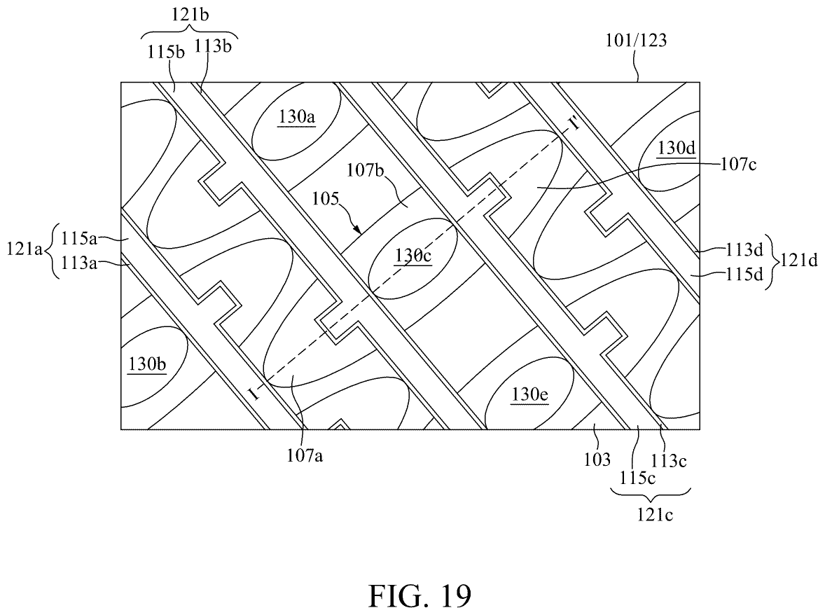

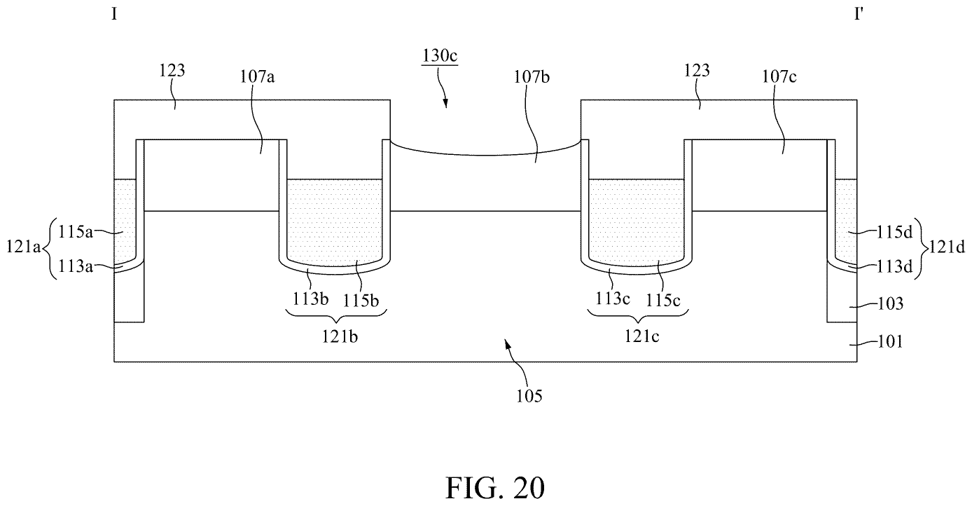

Next, the dielectric cap layer 123 is partially removed to form openings 130a, 130b, 130c, 130d, and 130e between the gate structures 121a, 121b, 121c, and 121d, as shown in FIGS. 19 and 20 in accordance with some embodiments. In some embodiments, the openings 130a, 130b, 130c, 130d, and 130e are bit line openings which expose the source/drain regions between the gate structures extending across the same active region. For example, as shown in FIG. 20, the opening 130c exposes the source/drain region 107b between the gate structures 121b and 121c.

The formation of the openings 130a, 130b, 130c, 130d, and 130e may include forming a patterned mask (not shown) over the dielectric cap layer 123, and etching the dielectric cap layer 123 by using the patterned mask as a mask. In some embodiments, a portion of the source/drain regions (e.g., the source/drain region 107b) exposed by the patterned mask is removed by the etching process. After the openings 130a, 130b, 130c, 130d, and 130e are formed, the pattered mask may be removed.

After the openings 130a, 130b, 130c, 130d, and 130e are formed, the bit line structures 141a, 141b, and 141c are formed over the dielectric cap layer 123, as shown in FIGS. 1 and 2 in accordance with some embodiments. In some embodiments, the bit line structures 141a, 141b, and 141c are electrically connected to the source/drain regions between the gate structures extending across the same active region. The respective step is illustrated as the step S25 in the method 10 shown in FIG. 6.

Each of the bit line structures 141a, 141b, and 141c includes a lower bit line layer and an upper bit line layer. For example, as shown in FIG. 2, the bit line structure 141b includes a lower bit line layer 135b and an upper bit line layer 137b over the lower bit line layer 135b. Although FIG. 2 only shows one of the openings is filled by one of the lower bit line layers (i.e., the opening 130c of FIG. 20 is filled by the lower bit line layer 135b), it is understood that the other openings (e.g., the openings 130a, 130b, 130d, and 130e) may be filled by the other lower bit line layers.

The formation of the bit line structures 141a, 141b, and 141c may include forming a lower bit line material (not shown) over the dielectric cap layer 123 and filling the openings 130a, 130b, 130c, 130d, and 130e, forming an upper bit line material (not shown) over the lower bit line material, forming a patterned mask (not shown) over the upper bit line material, and etching the upper bit line material and the lower bit line material by using the patterned mask as a mask.

The bit line structures 141a, 141b, and 141c include the remaining portions of the lower bit line material and the remaining portions of the upper bit line material. In some embodiments, the remaining portions of the lower bit line layer material and the remaining portions of the upper bit line layer have aligned sidewalls. After the bit line structures 141a, 141b, and 141c are formed, the pattered mask may be removed.

In some embodiments, each of the lower bit line layers (e.g., the lower bit line layer 135b) may be a single layer including doped polysilicon, metal, metal silicide, or metal compound, or may be a multi-layer including any combination of the above materials. In addition, the lower bit line layers may be formed by a deposition process, such as a CVD process, a PVD process, an ALD process, a MOCVD process, a sputtering process, or another applicable process. In some embodiments, each of the upper bit line layers (e.g., the upper bit line layer 137b) includes multilayers. Moreover, the upper bit line layers may include a metal or a metal compound. After the bit line structures 141a, 141b, and 141c are formed, the semiconductor device 100a is obtained.

Formation of the semiconductor device 100b is similar to the formation of the semiconductor 100a, the differences are described below. FIG. 21A is a top view illustrating a typical arrangement of active areas AA for shrinking active areas in the manufacturing of a semiconductor device. FIG. 21B is a top view illustrating an arrangement of long active areas 105 in the manufacturing of the semiconductor device 100b in accordance with various embodiments of the present disclosure.

With reference to FIGS. 6, 21A, and 21B, in step S11 of the method 10, the active areas are defined as a type of long active areas 105, in contrast to the typical arrangement of active areas used for shrinking active areas in the manufacturing of a semiconductor device, as shown in FIG. 21A. In FIG. 21A, directions d1 and d2 are orthogonal to each other, indicating that the long active areas 105 cannot be defined along the directions d1 and d2. By rotating the direction d1 to a new direction D1 (e.g., counterclockwise), the long active areas 105 can be defined along the direction D1. In addition, a plurality of dummy active areas 106 can be defined along a direction D2, which is a mirror image of the direction D1 with respect to a reference direction D3 (e.g., a horizontal direction). The long active areas 105 and the dummy active area 106 may be defined through different manufacturing processes, meaning the dummy active area 106 and the long active areas 105 can be located at different height levels.

Consequently, the arrangement of active areas in FIG. 21B may be implemented in two scenarios. The first scenario involves using both the long active areas 105 and the dummy active area 106, while the second scenario involves using only the long active areas 105, with the dummy active area 106 omitted.

FIG. 22 is a top view illustrating an intermediate stage of forming the trenches 501b and 501c during the formation of the semiconductor device 100b in accordance with some embodiments of the present disclosure. FIG. 23 is a cross-sectional view illustrating an intermediate stage of forming trenches 501b and 501c during the formation of the semiconductor device 100b along the sectional line C-C′ in FIG. 21B in accordance with some embodiments of the present disclosure.

With reference to FIGS. 6, 22 and 23, in step S15 of the method 10, the trenches 501b and 501c may be formed in an intermediate semiconductor structure, with gate structures 121a and 121d situated in the substrate 101, and a dielectric cap layer 123 covering both the gate structures 121a and 121d as well as the substrate 101. The intermediate semiconductor structure may be prepared in advanced through processes illustrate in the method 10. The formation of the trenches 501b and 501c is similar to the formation of the trenches 110a and 110d, and repeated descriptions are omitted. It should be noted that the trenches 501b and 501c are formed in the dielectric cap layer 123 and extending into the substrate 101, as shown in FIG. 23.

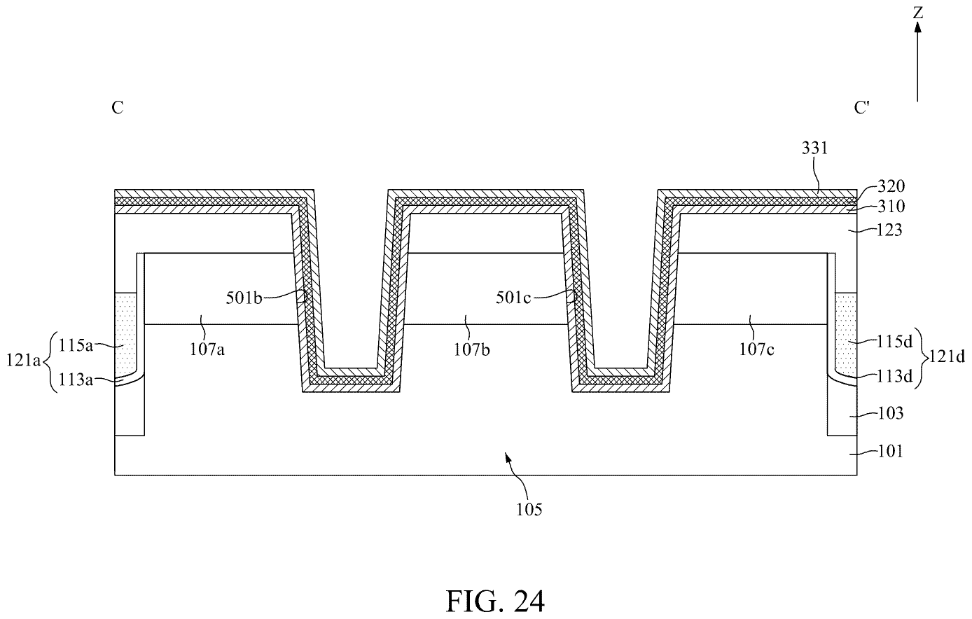

With reference to FIGS. 6 and 24, in step S17 of the method 10, an insulating layer 310 may be conformally formed in the trenches 501b and 501c, followed by the conformal formation of a barrier layer 320 on the insulating layer 310. In some embodiments, the insulating layer 310 may be formed by a thermal oxidation process. In some embodiments, the insulating layer 310 may be formed using a deposition process such as a chemical vapor deposition or an atomic layer deposition. The insulating layer 310 may include a high-k material, an oxide, a nitride, an oxynitride, or a combination thereof. The barrier layer 320 may be formed, for example, by atomic layer deposition. In some embodiments, the barrier layer 320 may be formed of, for example, titanium nitride. The barrier layer 320 may include a columnar grain structure.

With reference to FIG. 6 and FIGS. 24 to 27, in step S19, word line conductive layers 230b and 230c may be formed within the trenches 501b and 501c, respectively.

With reference to FIG. 24, a nucleation layer 331 may be conformally formed on the barrier layer 320. In some embodiments, the nucleation layer 331 may be a thin conformal layer that serves to facilitate the subsequent formation of a bulk material (i.e., the bulk layer 333) thereon. In some embodiments, the nucleation layer 331 may be formed by a pulsed nucleation layer method.

With reference to FIG. 25, a post-treatment may be performed to the nucleation layer 331. The nucleation layer 331 may be exposed to multiple pulses of reducing agents with interval times between the pulses. During an interval, no reducing agent flows to the nucleation layer 331. In some embodiments, the reducing agents such as diborane and a tungsten-containing precursor may alternatively flow (or introduce) to the nucleation layer 331.

In some embodiments, the flow rate of the diborane may be between about 100 sccm and about 500 sccm, or about 300 sccm. In some embodiments, the tungsten-containing precursor may include, for example, tungsten hexafluoride, tungsten hexachloride, or tungsten hexacarbonyl. The flow rate of the tungsten-containing precursor may be between about 100 sccm and about 500 sccm, or about 100 sccm. In some embodiments, the pulse time (or duration of pulse) may be between about 0.5 seconds and 5 seconds, or between about 1 seconds and 2 seconds. In some embodiments, the interval time between each pulse may be between about 2 seconds and about 5 seconds. In some embodiments, the number of pulses may be between 2 and 8. In some embodiments, the chamber pressure may be between about 2 Torr and about 100 Torr, or between about 20 Torr and about 40 Torr.

In some embodiments, the pulse time should be short enough to ensure that no or substantially no tungsten deposits. In some embodiments, the amount of the tungsten-containing precursor applied to the nucleation layer 331 during the post-treatment may be less than the amount of tungsten-containing precursor applied to the first barrier layer 320 during forming the nucleation layer 331. In some embodiments, the pulse time of the tungsten-containing precursor applied to the nucleation layer 331 during the post-treatment may be less than the pulse time of tungsten-containing precursor applied to the first barrier layer 320 during forming the nucleation layer 331.

In certain embodiments, the reducing agent and tungsten-containing precursor pulses may be as short as less than 1 second. In one example, diborane (B₂H₆) may be pulsed for 1 second, followed by a 1 second purge, followed by a tungsten hexafluoride (WF₆) pulse of 1 second, followed by a 2.5 second purge. This cycle is then repeated four times.

Not bound by a particular theory, it is believed that the introduction of the tungsten hexafluoride pulses between diborane pulses may help scavenge unreacted diborane, which otherwise promotes the onset of micropeeling from the surface of the nucleation layer 331.

In some embodiments, the post-treatment may be performed between about 10 seconds and about 50 seconds, or between about 10 seconds and about 30 seconds. Longer post-treatment time (or duration) may induce decomposition of diborane which has an adverse effect on the resistivity of the deposited bulk layer 333.

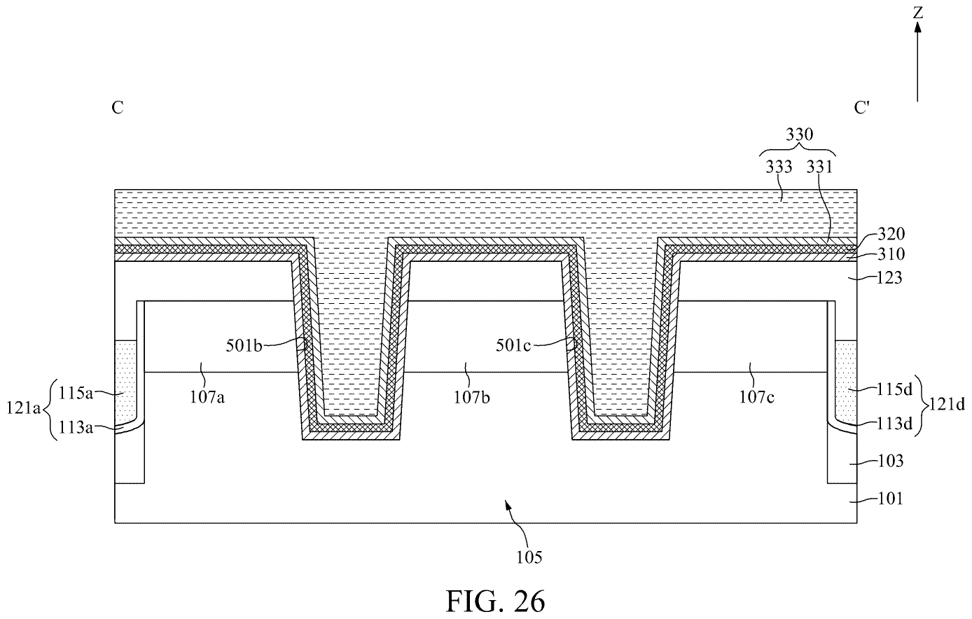

With reference to FIG. 26, the bulk layer 333 may be formed on the nucleation layer 331 and completely fill the trenches 501b and 501c. In some embodiments, the nucleation layer 331 and the bulk layer 333 may include tungsten. The bulk layer 333 and the nucleation layer 331 together configure a conductive layer 330. The bulk layer 333 may be formed by, for example, physical vapor deposition, atomic layer deposition, molecular layer deposition, chemical vapor deposition, in-situ radical assisted deposition, metalorganic chemical vapor deposition, molecular beam epitaxy, sputtering, plating, evaporation, ion beam deposition, electron beam deposition, laser assisted deposition, chemical solution deposition, or a combination thereof.

For example, the deposition of the bulk layer 333 using chemical vapor deposition may include flowing (or introducing) a tungsten-containing precursor and a co-reactant such as a reducing agent to the intermediate semiconductor device including the nucleation layer 331. Example process pressure may be between about 10 Torr and about 500 Torr. Example substrate temperature may be between about 250° C. and about 495° C. The tungsten-containing precursor may be, for example, tungsten hexafluoride, tungsten chloride, or tungsten hexacarbonyl. The reducing agent may be, for example, hydrogen gas, silane, disilane, hydrazine, diborane, or germane.

In some embodiments, the grain size of tungsten of the bulk layer 333 may be greater than 30 nm, than 50 nm, than 70 nm, than 80 nm, than 85 nm, or than 87 nm. In some embodiments, the bulk layer 333 may include alpha phase tungsten.

By employing the post-treatment to the nucleation layer 331, the deposited first conductive layer 330 may have tungsten with greater grain size and improved resistivity.

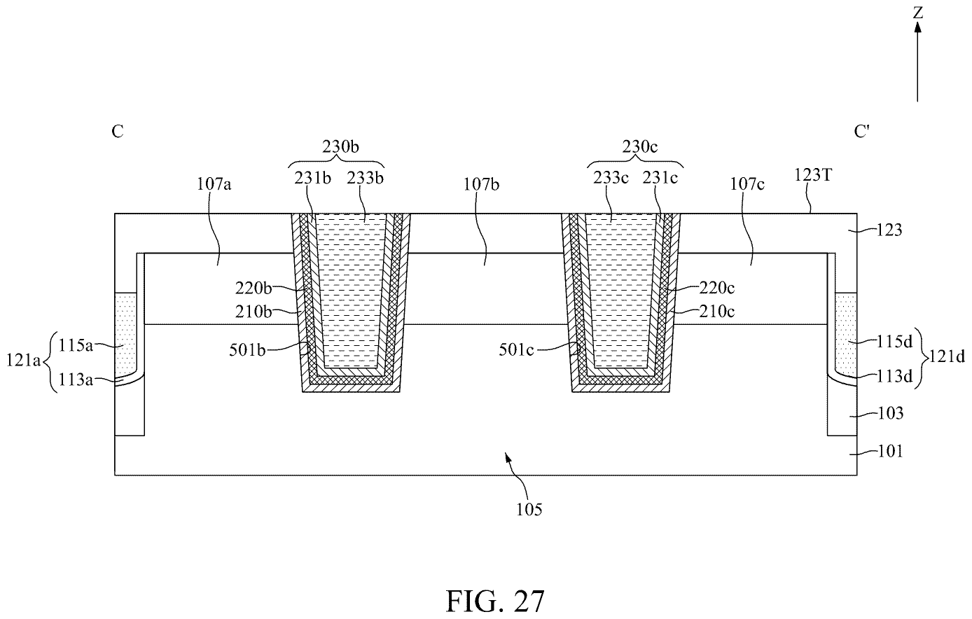

With reference to FIG. 27, a planarization process, such as chemical mechanical polishing, may be performed until a top surface 123T of the dielectric cap layer 123 is exposed. After the planarization process, the insulating layer 310 may be turned into word line insulating layers 210b and 210c in the trenches 501b and 501c, the barrier layer 320 may be turned into word line barrier layers 220b and 220c in the trenches 501b and 501c, the conductive layer 330 may be turned into word line conductive layers 230b and 230c in the trenches 501a and 501b, respectively. The word line conductive layer 230b includes a nucleation portion 231b and a bulk portion 233b. The word line conductive layer 230c includes a nucleation portion 231c and a bulk portion 233c. The nucleation portions 231b and 231c are originated from the nucleation layer 331 and the bulk portions 233b and 233c are originated from the bulk layer 333.

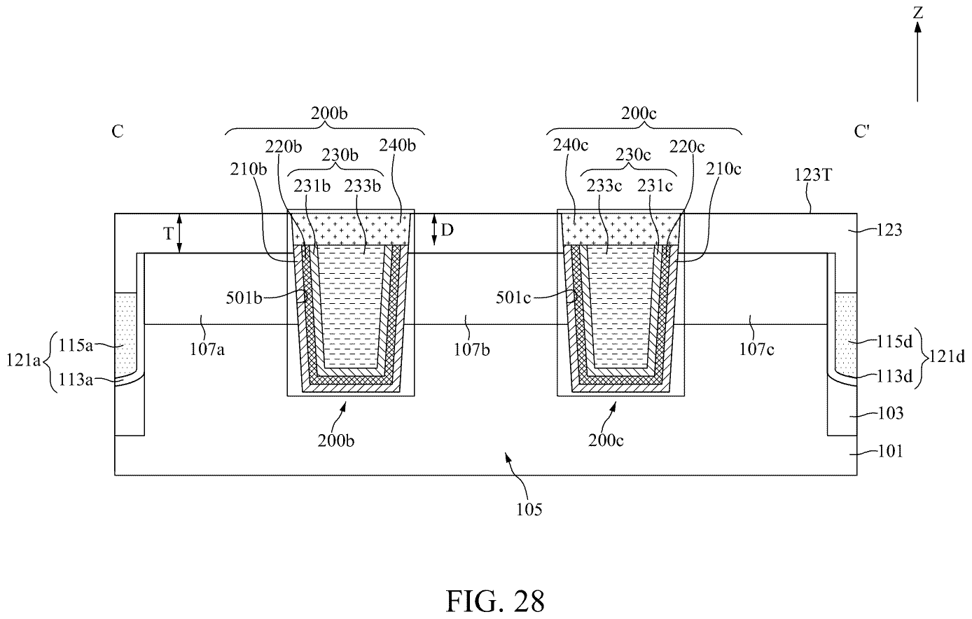

With reference to FIGS. 6 and 28, in steps S21 and S23 of the method 10, the word line conductive layers 230b and 230c may be recessed to form gate structures 200b and 200c. In addition, a first word line capping layer 240b and a second word line capping layer 240c may be disposed over and cap the word line conductive layers 230b and 230c, respectively.

With reference to FIG. 28, an etch process, such as an anisotropic dry etch process, may be performed to recess the word line insulating layers 210b and 210c, the word line barrier layers 220b and 220c, and the word line conductive layers 230b and 230c, respectively. An insulating material may be filled into the recesses. Subsequently, a planarization process, such as chemical mechanical polishing, may be performed until the top surface 123T of the dielectric capping layer 123 is exposed to remove excess material, provide a substantially flat surface for subsequent processing steps, and concurrently form word line capping layers 240b and 240c over and capping word line insulating layers 210b and 210c, the word line barrier layers 220b and 220c, and the word line conductive layers 230b and 230c, respectively. The insulating material may include, for example, silicon oxide, silicon nitride, silicon oxynitride, or silicon nitride oxide. The word line insulating layer 210b, the word line barrier layer 220b, the word line conductive layer 230b, and the word line capping layer 240b together configure the word line structure 200b. Similarly, the word line insulating layer 210c, the word line barrier layer 220c, the word line conductive layer 230c, and the word line capping layer 240c together configure the word line structure 200c.

It should be noted that a depth D of the recessing depends on a design of process requirements. In some embodiments, the depth D is less than, or equal to a thickness D of the dielectric capping layer 123 over the substrate 101. In other embodiments, the depth D may be greater than the thickness T of the dielectric capping layer 123 over the substrate 101.

After formation of the gate structures 200b and 200c, bit line structures, such as bit line structures 141a, 141b, and 141c, may be formed over the dielectric cap layer 123. As a result, the semiconductor device 100b is obtained. Processes and materials used to form the bit line structures are similar to, or same as, those used to form the bit line structures 141a, 141b, and 141c of the semiconductor device 100a, and details thereof are not repeated.

Embodiments of the semiconductor devices 100a and 100b are provided in this disclosure. In the semiconductor device 100a, the gate electrodes 115b and 115c of the semiconductor device 100a are disposed in the semiconductor substrate 101, and the source/drain regions 107a, 107b, and 107c are located in the active region 105 of the semiconductor substrate 101. The source/drain regions 107a and 107b are positioned at opposite sides of the gate electrode 115b, and the source/drain regions 107b and 107c are positioned at opposite sides of the gate electrode 115c. In addition, the gate electrode 115b includes the portion 115b1 extending across the active region 105 and the portion 115b2 extending into the source/drain region 107a, and the gate electrode 115c includes the portion 115c1 extending across the active region 105 and the portion 115c2 extending into the source/drain region 107c.

In the semiconductor device 100b, the word line conductive layer 230b and 230c (e.g., the gate electrodes) of the semiconductor device 100b are disposed in the dielectric cap layer 123 and extend into the semiconductor substrate 101. The source/drain regions 107a, 107b, and 107c are located in the long active region 105 of the semiconductor substrate 101. The source/drain regions 107a and 107b are positioned at opposite sides of the word line conductive layer 230b, and the source/drain regions 107b and 107c are positioned at opposite sides of the word line conductive layer 230c. In addition, the word line conductive layer 230b includes the portion 230b1 extending across the active region 105 and the portion 230b2 extending into the source/drain region 107a, and the word line conductive layer 230c includes the portion 230c1 extending across the active region 105 and the portion 230c2 extending into the source/drain region 107c.

From a top view perspective, as shown in FIGS. 1 and 4A, the gate electrodes 115b and 115c, as well as the word line conductive layer 230b and 230c may have “T” shape profiles.

By forming the T-shaped gate electrodes 115b and 115c, along with the word line conductive layer 230b and 230c, the effective gate width (i.e., effective channel width) may be increased, which can enhance the saturation current. Consequently, the gate control ability may be improved, leading to an increase in the operation speed of the device.

One aspect of the present disclosure provides a semiconductor device. The semiconductor device includes a semiconductor substrate having a plurality of long active areas; a first gate electrode disposed in a dielectric layer over the semiconductor substrate and extending into the substrate; and a first source/drain region and a second source/drain region disposed in the long active region and located at opposite sides of the first gate electrode. The long active areas extend along a first direction and are parallel to each other. The first gate electrode has a first portion extending across the long active region and a second portion extending into the first source/drain region.

Another aspect of the present disclosure provides a semiconductor device. The semiconductor device includes a semiconductor substrate; a plurality of long active areas disposed in the substrate; a first gate structure disposed in a dielectric layer over the semiconductor substrate and extending into the semiconductor substrate; and a first source/drain region and a second source/drain region disposed in the long active region and located at opposite sides of the first gate structure. The long active areas extend along a first direction and are parallel to each other. The first gate structure comprises a first word line insulating layer, a first word line barrier layer, a first word line conductive layer, and a first word line capping layer. The first word line conductive layer has a first portion extending across the long active region and a second portion extending into the first source/drain region.

Another aspect of the present disclosure provides a method for fabricating a semiconductor device. The method includes forming an isolation structure in a semiconductor substrate to define a long active region; forming a doped region in the long active region; forming a dielectric layer over the substrate; etching the dielectric layer and the semiconductor substrate to form a first trench and a second trench; and forming a first gate electrode in the first trench and a second gate electrode in the second trench. The first trench has a first portion extending across the doped region and a second portion extending away from the first portion, and the second trench has a third portion extending across the doped region and a fourth portion extending away from the third portion. The first portion of the first trench and the third portion of the second trench penetrate through the doped region to form a first source/drain region, a second source/drain region, and a third source/drain region, and the second source/drain region is located between the first trench and the second trench. The second portion of the first trench extends into the first source/drain region, and the fourth portion of the second trench extends into the third source/drain region. The second portion of the first trench exposes three sides of the first source/drain region, and the fourth portion of the second trench exposes three sides of the third source/drain region.

Another aspect of the present disclosure provides a method for fabricating a semiconductor device. The method includes providing a substrate; forming a word line trench in a dielectric layer over the substrate and into the substrate; conformally forming an insulating layer in the word line trench and conformally forming a barrier layer on the insulating layer; conformally forming a nucleation layer on the first barrier layer; performing a post-treatment to the nucleation layer, wherein the post-treatment comprises a reducing agent comprising diborane and a tungsten-containing precursor; forming a bulk layer on the nucleation layer; and performing a planarization process to turn the insulating layer, the barrier layer, and the conductive layer into a first word line insulating layer, a first word line barrier layer, a first word line conductive layer, a second word line insulating layer, a second word line barrier layer, and a second word line conductive layer, respectively. The nucleation layer and the bulk layer configure a conductive layer. The nucleation layer and the bulk layer comprise tungsten.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A method for preparing a semiconductor device, comprising:
forming an isolation structure in a semiconductor substrate to define a long active region;
forming a doped region in the long active region;
forming a dielectric layer over the substrate;
etching the dielectric layer and the semiconductor substrate to form a first trench and a second trench, wherein the first trench has a first portion extending across the doped region and a second portion extending away from the first portion, and the second trench has a third portion extending across the doped region and a fourth portion extending away from the third portion; and
forming a first gate electrode in the first trench and a second gate electrode in the second trench;
wherein the first portion of the first trench and the third portion of the second trench penetrate through the doped region to form a first source/drain region, a second source/drain region, and a third source/drain region, and the second source/drain region is located between the first trench and the second trench,
wherein the second portion of the first trench extends into the first source/drain region, and the fourth portion of the second trench extends into the third source/drain region, and
wherein the second portion of the first trench exposes three sides of the first source/drain region, and the fourth portion of the second trench exposes three sides of the third source/drain region.

2. The method of claim 1, wherein the second portion of the first trench and the fourth portion of the second trench extend in opposite directions.

3. The method of claim 1, wherein an extreme ultraviolet (EUV) lithography process is utilized to form the first trench and the second trench.

4. The method of claim 1, further comprising:
forming a first gate insulating layer in the first trench and surrounding the first gate electrode, and forming a second gate insulating layer in the second trench and surrounding the second gate electrode; and
forming a first gate barrier layer between the first gate insulating layer and the first gate electrode, and forming a second gate barrier layer between the second gate insulating layer and the second gate electrode.

5. The method of claim 4, further comprising:
forming a first capping layer over and capping the first gate electrode, the first gate insulating layer, and the first gate barrier layer; and
forming a second capping layer over and capping the second gate electrode, the second gate insulating layer, and the second gate barrier layer.
